(19) United States
(12) Patent Application Publication
(10) Pub. No.: US 2024/0234516 A1
(43) Pub. Date: Jul. 11, 2024

(54) TRANSISTOR GATE STACK FORMATION

(71) Applicant: INTERNATIONAL BUSINESS MACHINES CORPORATION, ARMONK, NY (US)

(72) Inventors: HUIMEI ZHOU, Albany, NY (US); Andrew Gaul, Halfmoon, NY (US); Nicolas Jean Loubet, GUILDERLAND, NY (US); MIAOMIAO WANG, Albany, NY (US)

(21) Appl. No.: 18/152,790

(22) Filed: Jan. 11, 2023

(51) Int. Cl. H01L 29/40; H01L 29/06; H01L 29/423; H01L 29/49; H01L 29/66; H01L 29/775; H01L 29/786

(52) U.S. Cl. CPC H01L 29/401; H01L 29/0673; H01L 29/42392; H01L 29/4908; H01L 29/66439; H01L 29/66545; H01L 29/6656; H01L 29/775; H01L 29/78696

(57) ABSTRACT

Embodiments of present invention provide a method of forming a gate structure of a transistor. The method includes forming a channel region of the gate structure; forming a high-k dielectric layer covering the channel region; forming a silicon monolayer covering the high-k dielectric layer; forming a sacrificial metal layer covering the silicon monolayer; forming a sacrificial silicon layer covering the sacrificial metal layer; subjecting the gate structure to a thermal anneal process, thereby transforming the silicon monolayer into a nitrogen-containing monolayer; removing the sacrificial silicon layer and the sacrificial metal layer; and forming a gate metal surrounding the channel region of the gate structure. A gate structure formed thereby is also provided.

### BACKGROUND

The present application relates to manufacturing of semiconductor integrated circuits. More particularly, it relates to method of forming gate stack of semiconductor transistor for reliability improvement and the structure formed thereby.

In forming semiconductor transistors, in particular in forming gate stack of the semiconductor transistors, a high-k dielectric layer is first formed on top of a silicon channel region of the transistors and the structure is then subjected to a thermal anneal process such as a laser spike anneal (LSA) or a rapid thermal anneal (RTA) process. However, the anneal process, while being a necessary process step in forming the gate stack, has been found to inadvertently and frequently cause negative bias temperature instability (NBTI) of the transistors. The NBTI is likely due to the fact that the anneal process also has caused nitrogen diffusion into the high-k dielectric layer that surrounds the silicon channel region of the transistors. NBTI is one of the key reliability concerns that limit the circuit lifetime and performance boost.

### SUMMARY

Embodiments of present invention provide a transistor structure. The transistor structure includes a channel region of a gate structure of a transistor; a high-k dielectric layer above the channel region; and a silicon-nitride layer directly on top of the high-k dielectric layer, where the high-k dielectric layer is substantially free of nitrogen.

In one embodiment, the channel region is a silicon nanosheet; the high-k dielectric layer surrounds the silicon nanosheet to form a gate-all-around structure; and the silicon-nitride layer surrounds the high-k dielectric layer.

In another embodiment, the high-k dielectric layer is a first high-k dielectric layer, and the transistor structure further includes a second high-k dielectric layer, where the second high-k dielectric layer is above and surrounds the silicon-nitride layer, the first high-k dielectric layer, and the silicon nanosheet.

In yet another embodiment, the first high-k dielectric layer has a first thickness and the second high-k dielectric layer has a second thickness, wherein the first thickness is larger than the second thickness.

In one more embodiment, the second high-k dielectric layer includes nitrogen to have a nitrogen concentration level that is higher than a nitrogen concentration level of the first high-k dielectric layer.

In one embodiment, the silicon-nitride layer is a nitrogen-containing monolayer transformed from a silicon monolayer after the silicon monolayer has trapped nitrogen during a thermal anneal process of the gate structure.

Embodiments of present invention provide a method of forming a gate structure of a transistor. The method includes forming a channel region of the gate structure; forming a first set of spacers at a first end of the channel region and a second set of spacers at a second end of the channel region; forming a high-k dielectric layer covering the channel region between the first set of spacers and the second set of spacers; forming a silicon monolayer covering the high-k dielectric layer; forming a sacrificial metal layer covering the silicon monolayer; forming a sacrificial silicon layer covering the sacrificial metal layer; subjecting the gate structure to a thermal anneal process, thereby transforming the silicon monolayer into a nitrogen-containing monolayer; and removing the sacrificial silicon layer and the sacrificial metal layer.

In one embodiment, the method further includes forming a gate metal covering the nitrogen-containing monolayer to form the gate structure. In another embodiment, the method further includes removing the nitrogen-containing monolayer. In yet another embodiment, the method further includes forming a gate metal covering the high-k dielectric layer to form the gate structure.

In one embodiment, the high-k dielectric layer is a first high-k dielectric layer, the method further includes forming a second high-k dielectric layer covering the silicon monolayer before forming the sacrificial metal layer and includes forming a gate metal covering the second high-k dielectric layer to form the gate structure.

In one embodiment, the sacrificial metal layer is a nitrogen scavenging layer. In another embodiment, forming the silicon monolayer includes depositing the silicon monolayer through an atomic layer deposition process. In yet another embodiment, subjecting the gate structure to the thermal anneal process includes subjecting the gate structure to an environment of high temperature ranging from about 700 degrees C. to about 1300 degrees C.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B-3A and 3B are demonstrative illustrations of cross-sectional views of a transistor structure in a process of manufacturing thereof according to one embodiment of present invention;

FIGS. 4A and 4B are demonstrative illustrations of cross-sectional views of a transistor structure in a process of manufacturing thereof according to a further embodiment of present invention;

FIGS. 5A and 5B-7A and 7B are demonstrative illustrations of cross-sectional views of a transistor structure in a process of manufacturing thereof according to another embodiment of present invention;

FIGS. 8A and 8B-10A and 10B are demonstrative illustrations of cross-sectional views of a transistor structure in a process of manufacturing thereof according to yet another embodiment of present invention; and

FIGS. 11-13 are demonstrative illustrations of flow-charts of processes of forming transistor structures according to various embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

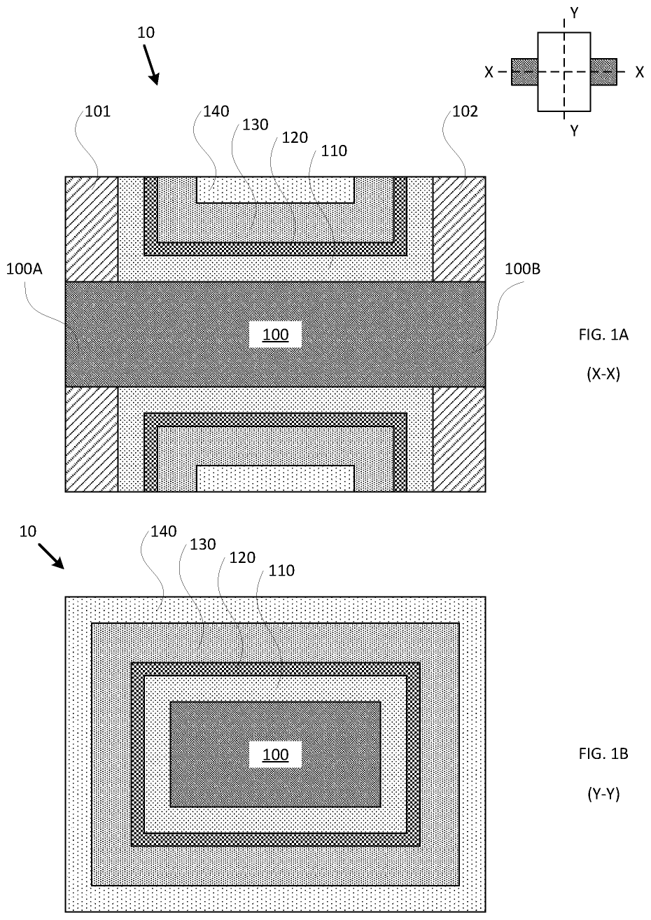

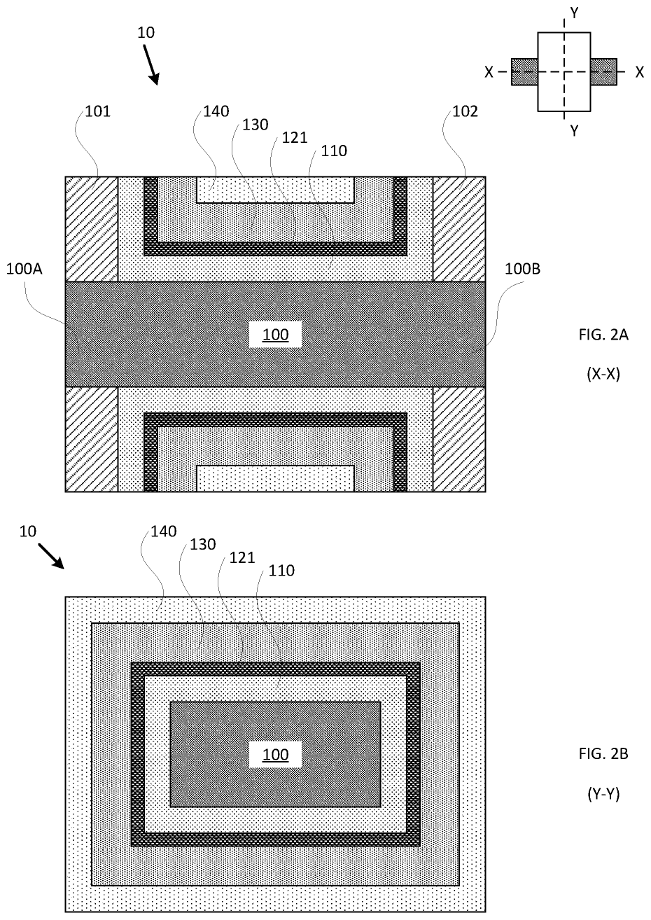

FIGS. 1A and 1B are demonstrative illustrations of cross-sectional views of a transistor structure in a step of manufacturing thereof according to one embodiment of present invention. More specifically, with reference to a simplified illustration of top view layout at the upper-right corner, FIG. 1A illustrates a cross-sectional view of a transistor structure 10 along a dashed line X-X, perpendicular to a gate of the transistor structure 10, and FIG. 1B illustrates a cross-sectional view of the transistor structure 10 along a dashed line Y-Y, parallel to the gate of the transistor structure 10. As it becomes clear below, FIGS. 2A and 2B to FIGS. 12A and 12B illustrate similar cross-sectional reviews of transistor structures 10, 11, 20, or 30, at different manufacturing stages in a manner corresponding respectively to FIGS. 1A and 1B according to various embodiments of present invention. Here, it is to be noted that transistor structures 10, 11, 20, and 30 are, as non-limiting examples, illustrated as nanosheet transistors and the use of nanosheet transistors is merely for the purpose of description of embodiments of present invention. A person skilled in the art will appreciate that embodiments of the present invention are not limited in this aspect and may be applied to other types of transistors such as, for example, planar transistors and/or fin-type transistors. For example, embodiments of present invention may be applied to forming a gate structure of a transistor where, in order to improve reliability of the transistor, it is important to prevent nitrogen from diffusing into a high-k dielectric layer that surrounds a channel region of the gate structure of the transistor.

More particularly, embodiments of present invention provide forming a nanosheet 100 such as a silicon (Si) nanosheet, a germanium (Ge) nanosheet, a silicon-germanium (SiGe) nanosheet, or other types of suitable semiconductor materials. In FIG. 1A, only one nanosheet 100 is demonstratively illustrated. However, many more nanosheets may be formed as well either above or below the nanosheet 100. The nanosheet 100 serves as a channel region of a gate structure of the transistor structure 10 to be formed thereupon. The nanosheet 100 may be referred to as a channel region as well hereinafter.

Embodiments of present invention provide forming a first set of spacers 101 at a first end 100A of the nanosheet 100; a second set of spacers 102 at a second end 100B of the nanosheet 100; and a high-k dielectric layer 110 surrounding the nanosheet 100 between the first set of spacers 101 and the second set of spacers 102, thereby forming a gate-all-around structure. The first set of spacers 101 and the second set of spacers 102 may include one or more spacers. The first set of spacers 101 and the second set of spacers 102 may be made of a dielectric material such as silicon-nitride (SiN) and the high-k dielectric layer 110 may be a layer of hafnium-oxide (HfO₂) that has a dielectric constant k larger than, for example, 4. The high-k dielectric layer 110 may be formed substantially nitrogen-free through a chemical vapor deposition (CVD) process, an atomic layer deposition (ALD) process, and/or a physical vapor deposition (PVD) process. Forming a high-k dielectric layer 110 of substantially nitrogen-free helps improve performance reliability of the transistor structure 10.

According to one embodiment, in order to keep the high-k dielectric layer 110 substantially nitrogen-free during subsequent process steps, a nitrogen trapping layer may be formed to surround and protect the high-k dielectric layer 110. For example, the nitrogen trapping layer may serve to capture or trap nitrogen during a thermal anneal process by preventing nitrogen from diffusing into the high-k dielectric layer 110, which would otherwise be detrimental to the performance of the transistor structure 10 in terms of reliability.

More specifically, embodiments of present invention provide forming a silicon monolayer 120, as a nitrogen trapping layer, to surround the high-k dielectric layer 110. The silicon monolayer 120, as the name suggests, may have a thickness as thin as around 1Å to 10Å, and may be formed through an ALD, a CVD, or a PVD process directly above, on top of, and surrounding the high-k dielectric layer 110, between the first set of spacers 101 and the second set of spacers 102.

After forming the silicon monolayer 120, embodiments of present invention provide forming a sacrificial metal layer 130 on top of and surrounding the silicon monolayer 120 and forming a sacrificial silicon layer 140 on top of and surrounding the sacrificial metal layer 130. The sacrificial metal layer 130 may be a nitrogen scavenging layer formed of thermally stable metal alloy including, for example, titanium-nitride (TiN), titanium-carbide (TiC), tantalum-nitride (TaN), or tantalum-carbide (TaC). The sacrificial metal layer 130 may be formed to have a thickness ranging from about 1 nm to 5 nm. In the meantime, the sacrificial silicon layer 140 may be a layer of amorphous silicon or poly-crystalline silicon.

FIGS. 2A and 2B are demonstrative illustrations of cross-sectional views of a transistor structure in a step of manufacturing thereof according to one embodiment of present invention. More specifically, following the step illustrated in FIGS. 1A and 1B, embodiments of present invention provide performing a thermal anneal process of the gate structure of the transistor structure 10. The thermal anneal process may be a rapid thermal anneal (RTA) process such as, for example, a laser spike anneal (LSA) process. During the LSA process, embodiments of present invention provide subjecting the gate structure of the transistor structure 10 to a high temperature environment, where the temperature rapidly surging up to about 700 degrees Celsius (C.) to about 1300 degrees C. for a duration of no more than about 5 seconds.

According to embodiments of present invention, during the LSA process, the silicon monolayer 120 may capture or trap elements of nitrogen such as, for example, nitrogen from an ambient environment or existing surrounding films and/or layers that contains nitrogen, thereby preventing nitrogen from diffusing into the high-k dielectric layer 110 underneath the silicon monolayer 120. In other words, the high-k dielectric layer 110 may remain substantially nitrogen-free, which helps improve or maintain performance reliability of the transistor structure 10. In the meantime, by capturing or trapping nitrogen, the silicon monolayer 120 may be transformed into a silicon-nitride layer 121, as being demonstratively illustrated in FIGS. 2A and 2B. In one embodiment, the silicon-nitride layer may be a nitrogen-containing monolayer.

Following the LSA process, a millisecond anneal process may optionally be used to further treat the transistor structure 10. The millisecond anneal process may be, for example, a laser anneal or a flash lamp anneal process, and may last for a duration of about 1 to 100 milliseconds as part of a process of forming the gate structure 10.

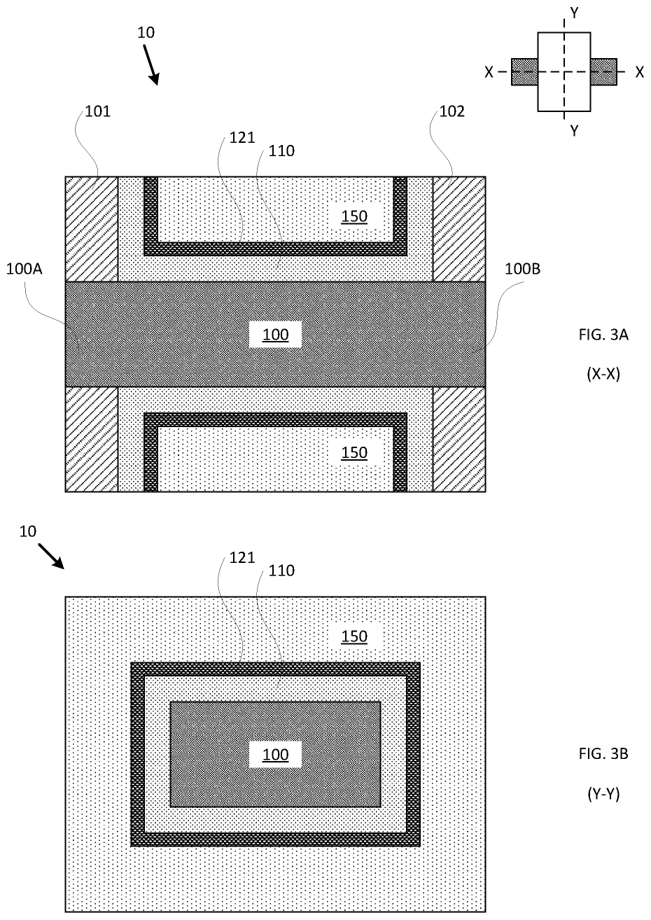

FIGS. 3A and 3B are demonstrative illustrations of cross-sectional views of a transistor structure in a step of manufacturing thereof according to one embodiment of present invention. More specifically, following the step illustrated in FIGS. 2A and 2B, embodiments of present invention provide, after the thermal anneal process, selectively removing the sacrificial silicon layer 140 and the sacrificial metal layer 130, leaving only the silicon-nitride layer 121 and the high-k dielectric layer 110 on top of and surrounding the channel region of the nanosheet 100. Embodiments of present invention provide further forming a gate metal 150 on top of and surrounding the silicon-nitride layer 121 thereby forming a metal gate of the transistor structure 10. The gate metal 150 may include one or more work-functional metals.

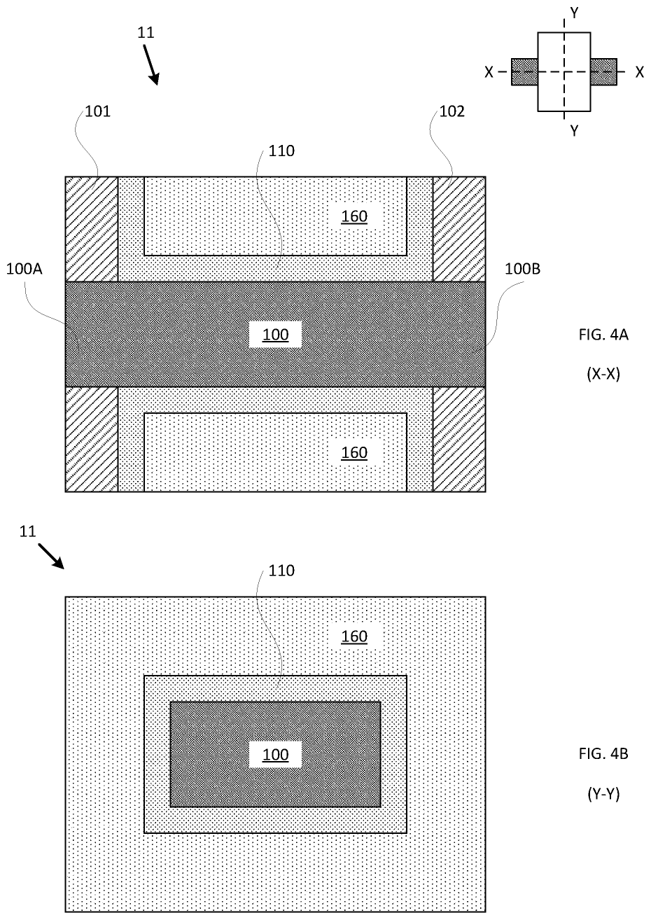

FIGS. 4A and 4B are demonstrative illustrations of cross-sectional views of a transistor structure 11 in a step of manufacturing thereof according to a further embodiment of present invention. More specifically, following the steps illustrated in FIGS. 1A and 1B to FIGS. 3A and 3B in forming the transistor structure 10, embodiments of present invention provide forming the transistor structure 11 by removing the silicon-nitride layer 121 to expose the high-k dielectric layer 110; and forming a gate metal 160 directly above, on top of, and surrounding the high-k dielectric layer 110 to form a metal gate of the transistor structure 11. In one embodiment, the gate metal 160 may include one or more work-function metals.

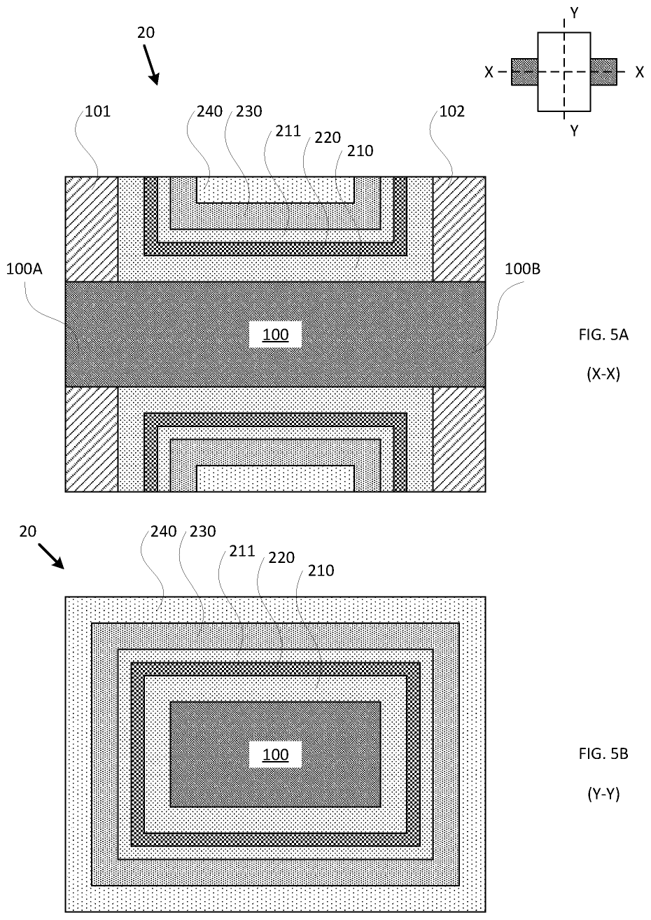

FIGS. 5A and 5B are demonstrative illustrations of cross-sectional views of a transistor structure in a step of manufacturing thereof according to another embodiment of present invention. In forming a transistor structure 20, many features, functions, and steps of manufacturing thereof may be similar to those of the transistor structures 10 and 11 as being described above, and thus these features, functions, and steps of manufacturing may not be repeated in the below description. However, a person skilled in the art will appreciate how these features, functions, and steps of manufacturing may be readily applied to the transistor structure 20.

More specifically, embodiments of present invention provide forming a nanosheet 100 that serves as a channel region of a gate structure of the transistor structure 20; forming a first set of spacers 101 at a first end 100A of the nanosheet 100; a second set of spacers 102 at a second end 100B of the nanosheet 100; and a first high-k dielectric layer 210 on top of and surrounding the nanosheet 100 between the first set of spacers 101 and the second set of spacers 102. The first high-k dielectric layer 210 may be formed substantially nitrogen-free through a CVD, an ALD, or a PVD process in a nitrogen-free environment such as, for example, a nitrogen-free chamber. Forming a first high-k dielectric layer 210 of substantially nitrogen-free helps improve performance reliability of the transistor structure 20.

According to one embodiment, a silicon monolayer 220, working as a nitrogen trapping layer, is then formed to surround the first high-k dielectric layer 210. The nitrogen trapping layer serves to capture or trap nitrogen during a subsequent thermal anneal process such that it prevents nitrogen from diffusing into the first high-k dielectric layer 210. The silicon monolayer 220, may have a thickness as thin as around 1Å to 10Å, and may be formed through an ALD, a CVD, or a PVD process directly above, on top of, and surrounding the first high-k dielectric layer 210.

According to one embodiment, after forming the silicon monolayer 220, a second high-k dielectric layer 211 may be formed on top of the silicon monolayer 220. In other words, the silicon monolayer 220 may be sandwiched between the first and second high-k dielectric layers 210 and 211. Generally, it is preferable to place the silicon monolayer 220 further away from the channel region of the nanosheet 100 such that after trapping nitrogen, the silicon monolayer 220, if not being removed, will have less impact on device reliability performance. Therefore, in one embodiment, the second high-k dielectric layer 211 may have a thickness that is thinner than a thickness of the first high-k dielectric layer 210.

Embodiments of present invention further provide forming a sacrificial metal layer 230, on top of the second high-k dielectric layer 211 and a sacrificial silicon layer 240 on top of the sacrificial metal layer 230. The sacrificial metal layer 230 may be a layer of TiN, TiC, TaN, or TaC material and may function as a nitrogen scavenging layer. The sacrificial silicon layer 240 may be a layer of amorphous silicon or poly-crystalline silicon.

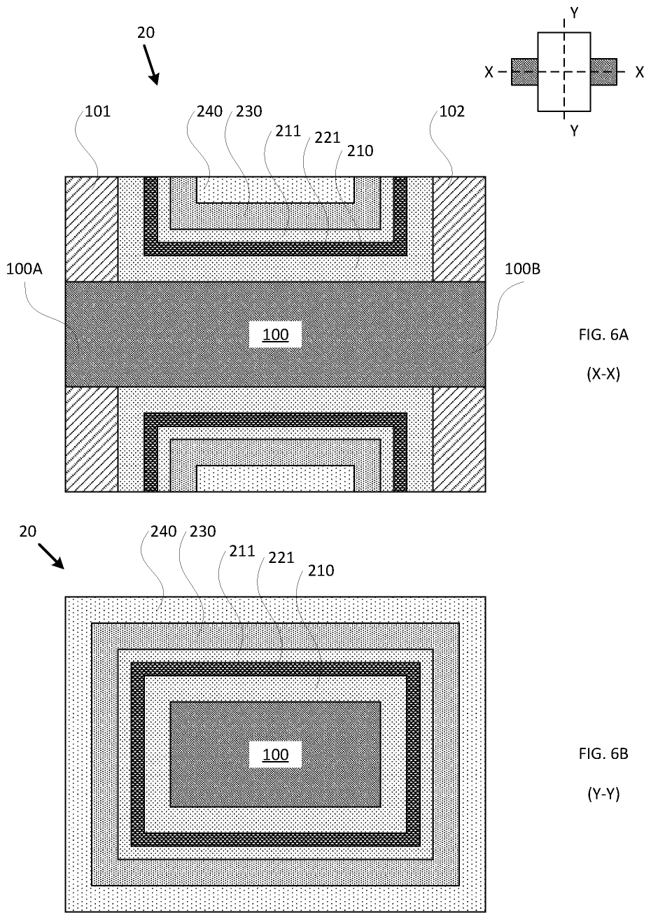

FIGS. 6A and 6B are demonstrative illustrations of cross-sectional views of a transistor structure in a step of manufacturing thereof according to one embodiment of present invention. More specifically, following the step illustrated in FIGS. 5A and 5B, embodiments of present invention provide performing a thermal anneal process of the gate structure of the transistor structure 20. During the thermal anneal process, the silicon monolayer 220 may be transformed into a silicon-nitride layer 221 after capturing and/or trapping nitrogen, as being demonstratively illustrated in FIGS. 6A and 6B. In one embodiment, the silicon-nitride layer 221 may be a nitrogen-containing monolayer. During the thermal anneal process, in one embodiment, some nitrogen may still get into the second high-k dielectric layer 211, resulting the second high-k dielectric layer 211 to have a nitrogen concentration level, despite being very low, that is higher than a nitrogen concentration level of the first high-k dielectric layer 210, which remains substantially nitrogen-free.

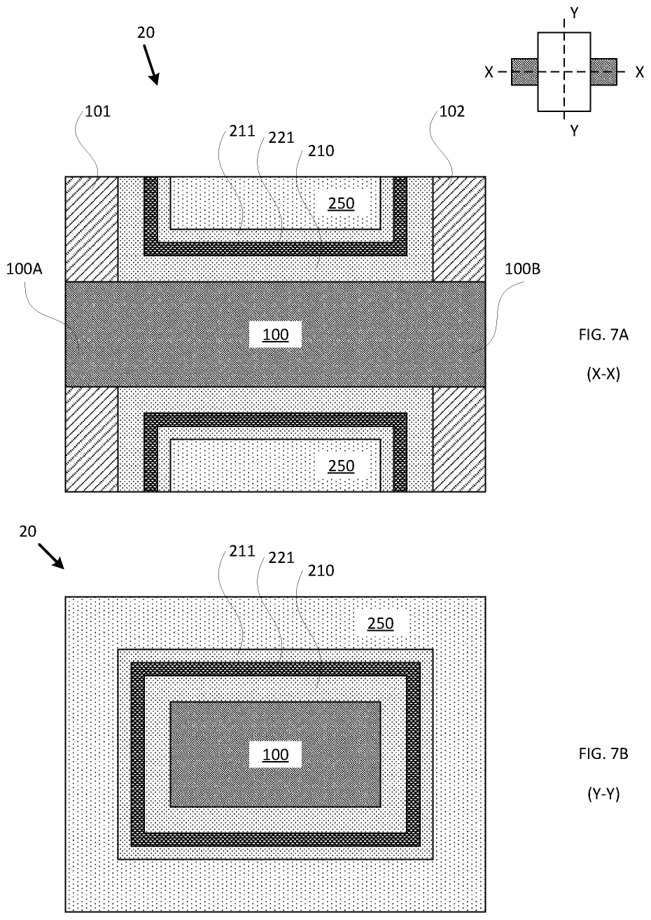

FIGS. 7A and 7B are demonstrative illustrations of cross-sectional views of a transistor structure in a step of manufacturing thereof according to one embodiment of present invention. More specifically, following the step illustrated in FIGS. 6A and 6B, embodiments of present invention provide, after the thermal anneal process, selectively removing the sacrificial silicon layer 240 and the sacrificial metal layer 230, leaving the second high-k dielectric layer 211, the silicon-nitride layer 221, and the first high-k dielectric layer 210 on top of and surrounding the channel region of the nanosheet 100. Embodiments of present invention provide further forming a gate metal 250 above the second high-k dielectric layer 211 to form a metal gate of the transistor structure 20. In one embodiment, the gate metal 250 may include one or more work-function metals.

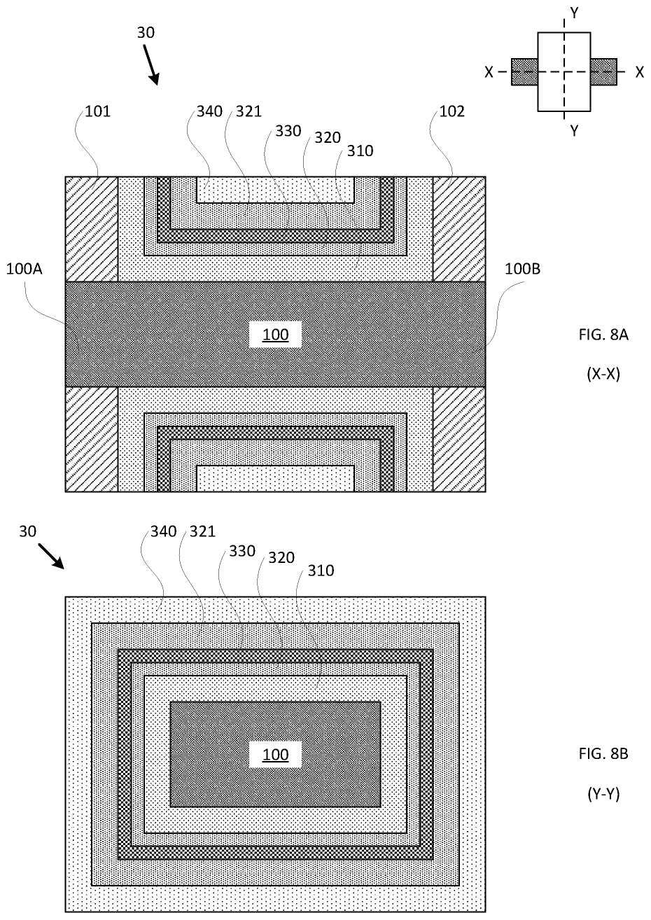

FIGS. 8A and 8B are demonstrative illustrations of cross-sectional views of a transistor structure in a step of manufacturing thereof according to yet another embodiment of present invention. As being described above, in forming a transistor structure 30, many features, functions, and steps of manufacturing may be similar to that of transistor structures 10, 11, and 20, and thus these features, functions, and steps of manufacturing may not be repeated in the below description. Moreover, a person skilled in the art will appreciate how these features, functions, and steps of manufacturing may be readily applied to the manufacturing of the transistor structure 30.

More specifically, embodiments of present invention provide forming a nanosheet 100 that serves as a channel region of a gate structure of the transistor structure 30; forming a first set of spacers 101 at a first end 100A of the nanosheet 100; a second set of spacers 102 at a second end 100B of the nanosheet 100; and a high-k dielectric layer 310 on top of and surrounding the nanosheet 100 between the first set of spacers 101 and the second set of spacers 102. The high-k dielectric layer 310 may be formed substantially nitrogen-free through a CVD, an ALD, or a PVD process in a nitrogen-free environment such as, for example, a nitrogen-free chamber. Forming a high-k dielectric layer 310 of substantially nitrogen-free helps improve performance reliability of the transistor structure 30.

According to one embodiment, a first sacrificial metal layer 320 may be formed to surround the high-k dielectric layer 310 and a nitrogen trapping layer 330 may then be formed to surround the first sacrificial metal layer 320. In one embodiment, the nitrogen trapping layer 330 may be a metal oxide layer, such as a titanium-oxide (TiO) layer, or a silicon monolayer. The nitrogen trapping layer 330 serves to capture or trap nitrogen during a subsequent thermal anneal process such that it prevents nitrogen from diffusing into the high-k dielectric layer 310. The nitrogen trapping layer 330 may have a thickness around 1Å to 30Å, and may be formed through an ALD, a CVD, or a PVD process directly above, on top of, and surrounding the first sacrificial metal layer 320.

Next, a second sacrificial metal layer 321 may be formed on top of the nitrogen trapping layer 330. By doing so, the nitrogen trapping layer 330 becomes sandwiched between the first and second sacrificial metal layers 320 and 321. The first and second sacrificial metal layers 320 and 321 may be formed to have a same or different thicknesses. In one instance, the thickness of the first sacrificial metal layer 320 is substantially close to zero and the transistor structure 30 is substantially identical to the transistor structure 10. After forming the second sacrificial metal layer 321, a sacrificial silicon layer 340 may be formed on top of and surrounding the second sacrificial metal layer 321. The first and second sacrificial metal layers 320 and 321 may be layers of TiN, TiC, TaN, or TaC and may both be nitrogen scavenging layers. The sacrificial silicon layer 340 may be a layer of amorphous silicon or poly-crystalline silicon. The sacrificial silicon layer 340 may also be replaced with a metal oxide layer to trap nitrogen.

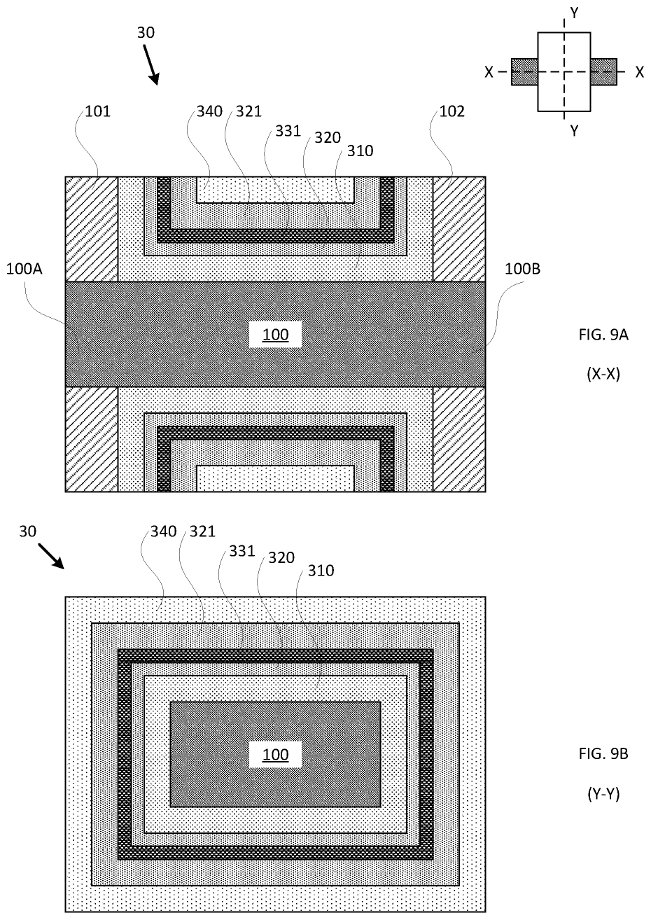

FIGS. 9A and 9B are demonstrative illustrations of cross-sectional views of a transistor structure in a step of manufacturing thereof according to one embodiment of present invention. More specifically, following the step illustrated in FIGS. 8A and 8B, embodiments of present invention provide performing a thermal anneal process of the gate structure of the transistor structure 30. During the thermal anneal process, the nitrogen trapping layer 330 may be transformed into a nitrogen-bonded layer 331 after capturing and/or trapping nitrogen, as being demonstratively illustrated in FIGS. 9A and 9B. In one embodiment, the nitrogen-bonded layer 331 may be a nitrogen-containing monolayer.

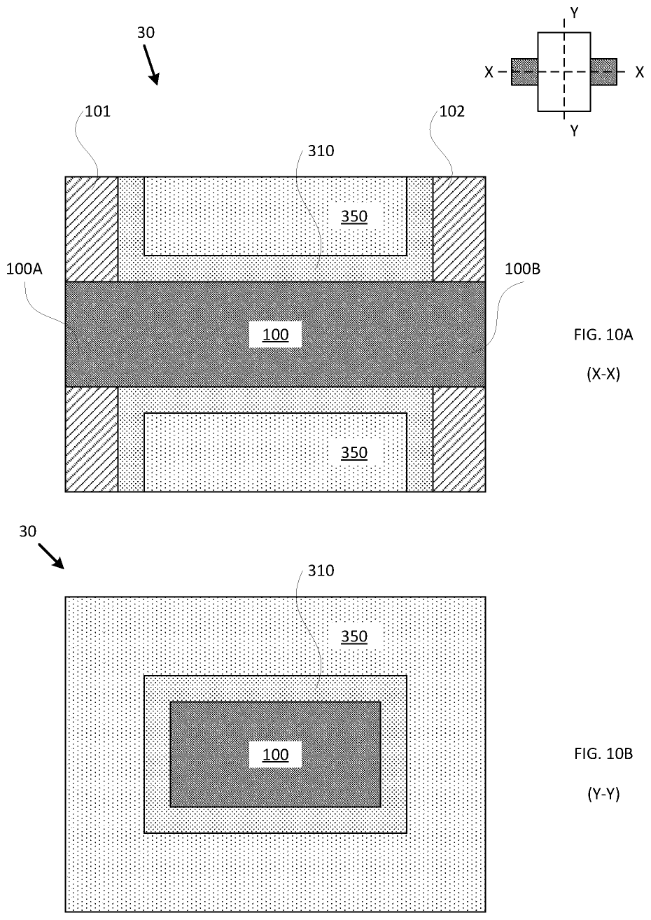

FIGS. 10A and 10B are demonstrative illustrations of cross-sectional views of a transistor structure in a step of manufacturing thereof according to one embodiment of present invention. More specifically, following the step illustrated in FIGS. 9A and 9B, embodiments of present invention provide, after the thermal anneal process, selectively removing the sacrificial silicon layer 340 and the second sacrificial metal layer 321; selectively removing the nitrogen-bonded layer 331; and selectively removing the first sacrificial metal layer 320 to expose the underneath the high-k dielectric layer 310. Embodiments of present invention provide further forming a gate metal 350 above the exposed high-k dielectric layer 310 to form a metal gate of the transistor structure 30. In one embodiment, the gate metal 350 may include one or more work-function metals.

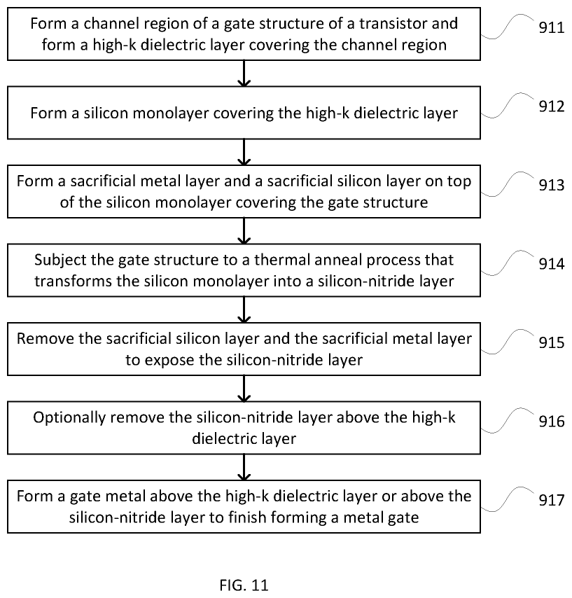

FIG. 11 is a demonstrative illustration of flow-chart of processes of forming transistor structures according to one embodiment of present invention. More specifically, embodiments of present invention provide a method of (911) forming a channel region of a gate structure of a transistor and forming a high-k dielectric layer covering the channel region of the transistor; (912) forming a silicon monolayer covering the high-k dielectric layer; (913) forming a sacrificial metal layer and subsequently a sacrificial silicon layer, such as an amorphous or poly-crystalline silicon layer, on top of the silicon monolayer covering the gate structure; (914) subjecting the gate structure of the transistor to a thermal anneal process that consequently transforms the silicon monolayer into a silicon-nitride layer by capturing and/or trapping nitrogen during the thermal anneal process; (915) removing the sacrificial silicon layer and the sacrificial metal layer to expose the silicon-nitride layer; (916) removing, optionally, the silicon-nitride layer above the high-k dielectric layer; and (917) forming a gate metal above the high-k dielectric layer or, when the silicon-nitride layer is not removed, above the silicon-nitride layer to finish forming a metal gate of the transistor.

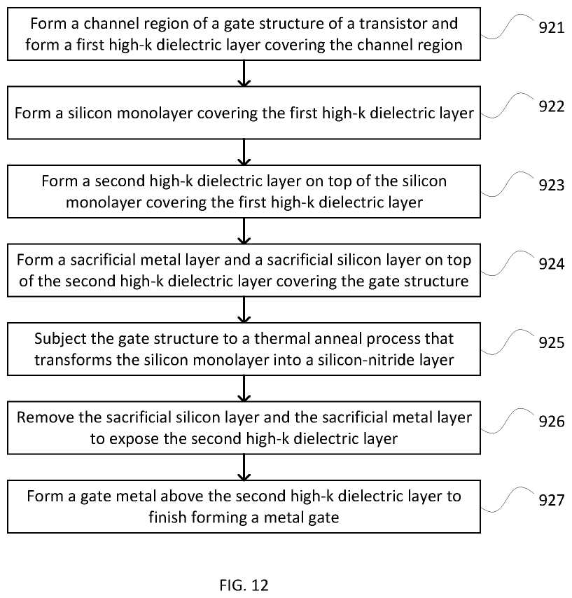

FIG. 12 is a demonstrative illustration of flow-chart of processes of forming transistor structures according to one embodiment of present invention. More specifically, embodiments of present invention provide a method of (921) forming a channel region of a gate structure of a transistor and forming a first high-k dielectric layer covering the channel region of the transistor; (922) forming a silicon monolayer covering the first high-k dielectric layer; (923) forming a second high-k dielectric layer on top of the silicon monolayer covering the first high-k dielectric layer; (924) forming a sacrificial metal layer and subsequently a sacrificial silicon layer, such as an amorphous or poly-crystalline silicon layer, on top of the second high-k dielectric layer covering the gate structure; (925) subjecting the gate structure to a thermal anneal process that consequently transforms the silicon monolayer into a silicon-nitride layer by capturing or trapping nitrogen during the thermal anneal process; (926) removing the sacrificial silicon layer and the sacrificial metal layer to expose the second high-k dielectric layer; and (927) forming a gate metal above the second high-k dielectric layer to finish forming a metal gate of the transistor.

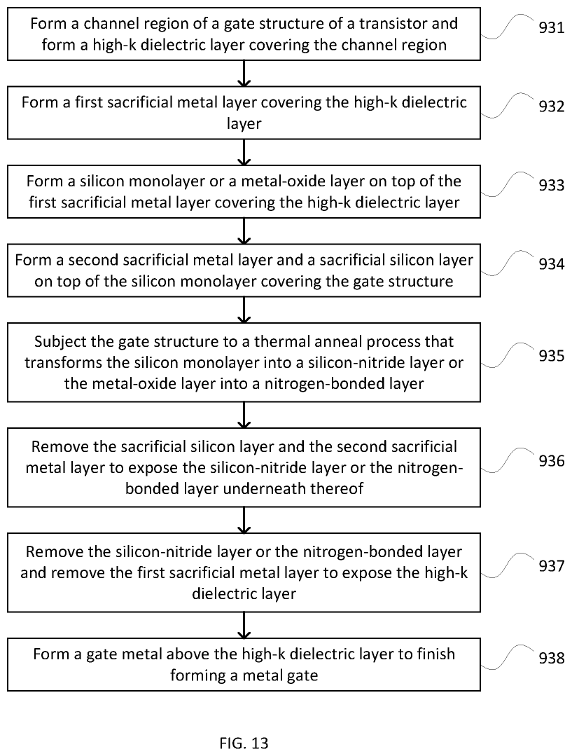

FIG. 13 is a demonstrative illustration of flow-chart of processes of forming transistor structures according to one embodiment of present invention. More specifically, embodiments of present invention provide a method of: (931) forming a channel region of a gate structure of a transistor and forming a high-k dielectric layer covering the channel region of the transistor; (932) forming a first sacrificial metal layer covering the high-k dielectric layer; (933) forming a silicon monolayer or a metal oxide layer on top of the first sacrificial metal layer covering the high-k dielectric layer; (934) forming a second sacrificial metal layer and subsequently a sacrificial silicon layer, such as an amorphous or poly-crystalline silicon layer, on top of the silicon monolayer covering the gate structure; (935) subjecting the gate structure to a thermal anneal process that consequently transforms the silicon monolayer into a silicon-nitride layer or the metal oxide layer into a nitrogen-bonded layer by capturing or trapping nitrogen during the thermal anneal process; (936) removing the sacrificial silicon layer and the second sacrificial metal layer to expose the silicon-nitride layer or the nitrogen-bonded layer; (937) removing the silicon-nitride or the nitrogen-bonded layer and remove the first sacrificial metal layer to expose the high-k dielectric layer; and (938) forming a gate metal above the high-k dielectric layer to finish forming a metal gate of the transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A transistor structure comprising:
a channel region of a gate structure of a transistor;
a high-k dielectric layer above the channel region; and
a silicon-nitride layer directly on top of the high-k dielectric layer,
wherein the high-k dielectric layer is substantially free of nitrogen.

2. The transistor structure of claim 1, wherein the channel region is a silicon nanosheet; the high-k dielectric layer surrounds the silicon nanosheet to form a gate-all-around structure; and the silicon-nitride layer surrounds the high-k dielectric layer.

3. The transistor structure of claim 2, wherein the high-k dielectric layer is a first high-k dielectric layer, further comprising a second high-k dielectric layer, wherein the second high-k dielectric layer is above and surrounds the silicon-nitride layer, the first high-k dielectric layer, and the silicon nanosheet.

4. The transistor structure of claim 3, wherein the first high-k dielectric layer has a first thickness and the second high-k dielectric layer has a second thickness, wherein the first thickness is larger than the second thickness.

5. The transistor structure of claim 4, wherein the second high-k dielectric layer includes nitrogen to have a nitrogen concentration level that is higher than a nitrogen concentration level of the first high-k dielectric layer.

6. The transistor structure of claim 1, wherein the silicon-nitride layer is a nitrogen-containing monolayer transformed from a silicon monolayer after the silicon monolayer has trapped nitrogen during a thermal anneal process of the gate structure.

7. A transistor structure comprising:
a channel region of a gate structure of a transistor;
a first and a second spacer at a first and a second end of the channel region;
a high-k dielectric layer on top of and surrounding the channel region of the gate structure of the transistor, the high-k dielectric layer being between the first and second spacers and substantially nitrogen-free; and
a silicon-nitride layer surrounding the high-k dielectric layer.

8. The transistor structure of claim 7, wherein the high-k dielectric layer is a first high-k dielectric layer, further comprising a second high-k dielectric layer on top of and surrounding the silicon-nitride layer, and wherein the silicon-nitride layer is a nitrogen-containing monolayer.

9. The transistor structure of claim 7, wherein the channel region is a silicon nanosheet; the second high-k dielectric layer is thinner than the first high-k dielectric layer and has a nitrogen concentration level that is higher than a nitrogen concentration level of the first high-k dielectric layer.

10. A method of forming a gate structure of a transistor, the method comprising:
forming a channel region of the gate structure;
forming a first set of spacers at a first end of the channel region and a second set of spacers at a second end of the channel region;
forming a high-k dielectric layer covering the channel region between the first set of spacers and the second set of spacers;
forming a silicon monolayer covering the high-k dielectric layer;
forming a sacrificial metal layer covering the silicon monolayer;
forming a sacrificial silicon layer covering the sacrificial metal layer;
subjecting the gate structure to a thermal anneal process, thereby transforming the silicon monolayer into a nitrogen-containing monolayer; and
removing the sacrificial silicon layer and the sacrificial metal layer.

11. The method of claim 10, further comprising forming a gate metal covering the nitrogen-containing monolayer to form the gate structure.

12. The method of claim 10, further comprising removing the nitrogen-containing monolayer.

13. The method of claim 12, further comprising forming a gate metal covering the high-k dielectric layer to form the gate structure.

14. The method of claim 10, wherein the high-k dielectric layer is a first high-k dielectric layer, further comprising forming a second high-k dielectric layer covering the silicon monolayer before forming the sacrificial metal layer.

15. The method of claim 14, further comprising forming a gate metal covering the second high-k dielectric layer to form the gate structure.

16. The method of claim 10, wherein the sacrificial metal layer is a second sacrificial metal layer, further comprising forming a first sacrificial metal layer covering the high-k dielectric layer before forming the silicon monolayer.

17. The method of claim 16, further comprising removing the nitrogen-containing monolayer and the first sacrificial metal layer and forming a gate metal covering the high-k dielectric layer to form the gate structure.

18. The method of claim 10, wherein the sacrificial metal layer is a nitrogen scavenging layer.

19. The method of claim 10, wherein forming the silicon monolayer comprises depositing the silicon monolayer through an atomic layer deposition process.

20. The method of claim 10, wherein subjecting the gate structure to the thermal anneal process comprises subjecting the gate structure to an environment of high temperature ranging from about 700 degrees Celsius to about 1300 degrees Celsius.
